(19) United States
(12) Patent Application Publication
(10) Pub. No.: US 2012/0025063 A1
(43) Pub. Date: Feb. 2, 2012

(54) LINEAR/LOGARITHMIC CAPACITIVE TRANS-IMPEDANCE AMPLIFIER CIRCUIT

(75) Inventors: Eric Woodbury, Santa Barbara, CA (US); Mark Alan Massie, Santa Ynez, CA (US)

(73) Assignee: Nova Research, Inc., Solvang, CA (US)

(21) Appl. No.: 13/192,391

(22) Filed: Jul. 27, 2011

Related U.S. Application Data
(60) Provisional application No. 61/368,441, filed on Jul. 28, 2010.

(51) Int. Cl. H03F 3/08

(52) U.S. Cl. 250/214 A

(57) ABSTRACT

A dual mode amplifier for photodiode output reads a photodiode providing a current input. An integration capacitor is connected to receive the current input and connected to a voltage output node. An input capacitor is also connected to receive the voltage input and drives an operational amplifier having an output connect to the voltage output node. A correlated double-sample (CDS) capacitor is connected to the voltage output node and a sample and hold circuit incorporating a sample and hold capacitor for sampling the CDS capacitor. A log function on (LOGON) switch is connected between the operational amplifier output and the voltage output node and a reset switch connected to short the photodiode. The LOGON switch sequentially operates in conjunction with the reset switch at the end of an integration time allowing the integration capacitor to retain an integrated current plus a log voltage by closing of the reset switch shorting the detector photodiode and offsetting the voltage on the integration capacitor into the negative voltage direction.

### REFERENCE TO RELATED APPLICATIONS

This application claims priority of U.S. Provisional Application Ser. No. 61/368,441 filed on Jul. 28, 2010 entitled LINEAR/LOGARITHMIC CAPACITIVE TRANS-IMPEDANCE AMPLIFIER CIRCUIT the disclosure of which is incorporated herein by reference.

### BACKGROUND INFORMATION

1. Field

Embodiments of the disclosure relate generally to the field of photodiode control in detector systems and more particularly to embodiments for providing a capacitive transimpedance amplifier control circuit for linear response to a lower portion of the output swing and a logarithmic response to an upper portion of the output swing of the detector.

2. Background

A common circuit for use with photodiodes, such as visible, UV or IR and in quantities of one or millions, is the trans-impedance amplifier (TIA). This is also called a current-to-voltage converter. In the TIA circuit, a photodiode is connected to the input in such a way that the current from the diode flows in a feedback element that can be a resistor or a capacitor or combination. The current flow affects an output voltage change that is linear with light flux. The output voltage remains linear as long as the output of the amplifier is within its operating range. If the amplifier's output exceeds its output range (saturates), the output voltage can no longer move and no longer provides feedback and typically the bias voltage (the voltage across the diode) can no longer be maintained. If the photodiode were initially biased in a zero or near-zero (slightly reverse) bias, then this will become forward bias from lack of feedback and from continued flux on the photodiode detector. In previous circuits, this non-linear behavior made no difference to the output voltage. The saturated amplifier resulted in a “saturated” signal from too much flux.

The current-voltage relationship exhibited by a photodiode junction is given by:

$$I = {I}_{sa} [ exp ( \frac{{qV}_{d}}{nkT} ) - 1 ] - q η {Q}_{b} A$$

where:
I=photodiode current
Iₛₐ=photodiode saturation current
q=electron charge
V_{d}=photodiode voltage
n=efficiency factor for photodiodes (n=1 for ideal diode and n=2 to 3 for real devices)
T=diode operating temperature
η=photodiode quantum efficiency
Q_{b}=photodiode incident flux density
A=photodiode area
k=Boltzmann's constant

### see The Infrared & Electro-Optical Systems Handbook, Vol. 3, Electro-Optical Components, W. D. Rogatto, Editor, Ch. 4, Detectors, pg. 209, ERIM and SPIE Press, 1993.

It is therefore desirable to provide a photo diode control circuit which avoids saturation to provide flexibility for high flux input to the photodiode detector.

### SUMMARY

Exemplary embodiments provide a dual mode amplifier circuit to receive output from a photodiode. In a first mode the amplifier portion of the circuit is in a linear range and the diode is operating in its current mode. In a second mode, the amplifier has saturated and as such no longer acts as an amplifier and the diode is allowed to self-bias into the voltage mode or log mode operation. In the first mode, the amplifier acts as a capacitive trans-impedance amplifier (CTIA) circuit with the photodiode providing a current input. An integration capacitor (feedback capacitor) is connected to receive the current and produces a voltage output. An input capacitor is also connected to receive the current input and drives an operational amplifier having an output connected to the voltage output node. For one exemplary embodiment, a correlated double-sample (CDS) capacitor is connected to the voltage output node. A sample and hold circuit incorporating a sample and hold capacitor samples the amplifier output. A log function on (LOGON) switch is connected between the operational amplifier output and the voltage output node and a reset switch connected to short the photodiode. The LOGON switch sequentially operates in conjunction with the reset switch at the end of an integration time allowing the integration capacitor to retain an integrated current (voltage) plus a log voltage with closing of the reset switch shorting the detector photodiode and offsetting the voltage on the integration capacitor into the negative voltage direction.

The exemplary embodiment provides a method for linear and logarithmic measurement of a diode detector by obtaining a current/voltage input from a diode detector which is then integrated/sampled on an integration capacitor and input through a capacitor to an operational amplifier. A double-sample capacitor is charged with an output from the operational amplifier and the integration capacitor. The output of the operational amplifier is interrupted after an integration period and the linear input from the integration capacitor is sampled for a first sample period. The diode detector is then shorted for sampling the logarithmic input voltage for a second sample period and a sample-and-hold circuit is activated to read the double-sample capacitor which now has the sum voltages of the linear mode and the log response. The amplifier and CDS capacitor are then reset for the next frame.

The features, functions, and advantages that have been discussed can be achieved independently in various embodiments of the present invention or may be combined in yet other embodiments further details of which can be seen with reference to the following description and drawings

### BRIEF DESCRIPTION OF THE DRAWINGS

FIG. 1 is a circuit schematic of an embodiment of a capacitive trans-impedance amplifier control circuit for a photodiode;

FIG. 2 is a timing diagram of the signal elements of the circuit of FIG. 1;

FIG. 3 is a graph of output voltage with respect to time for the circuit;

FIG. 4 is a voltage graph for a first sampling approach and,

FIG. 5 is a voltage graph for a second sampling approach.

### DETAILED DESCRIPTION

For the case in which the photodiode current I is set to zero (i.e., the “open circuit” case), re-arrangement of this equation produces an expression for the “open circuit diode voltage” that indicates that this voltage will be proportional to the logarithm of input flux density:

$${V}_{d} = \frac{nkT}{q} ln \vert \frac{q η {Q}_{b} A}{{I}_{s}} \vert$$

Open circuit and “forward biased” (i.e., positive V_{d} regime) operation of the diode will produce a logarithmic voltage response of V_{d} to input flux density. A “reverse biased” (i.e., negative V_{d} regime) operation will produce a linear photodiode voltage response.

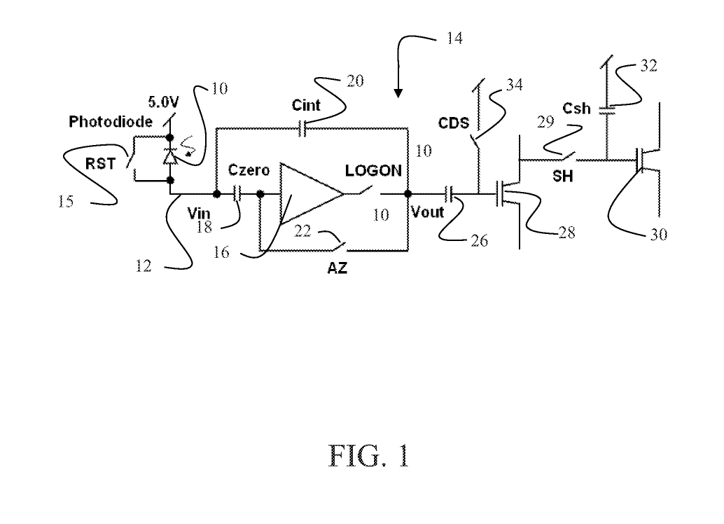

Referring to FIG. 1, an embodiment of a capacitive trans-impedance amplifier (CTIA) circuit integrates the photodiode current across the integration capacitor producing a voltage at Vout. (or in an alternative description, the change in voltage across the amplifier's feedback element, whether capacitor or resistor). The photodiode is connected between a 5.0V rail supply and an input, Vin, 12 for the CTIA 14. The supply voltage for the exemplary embodiment may be altered in alternative embodiments. A reset switch, RST, 15 is provided for the photodiode as will be described in greater detail subsequently. The CTIA incorporates an operational amplifier 16 with an input capacitor, Czero, 18 and an integration capacitor, Cint, 20. An auto-zero switch 22, to be described in greater detail subsequently, is connected in parallel with the op amp. Output of the CTIA, Vout, 24 is provided through logarithmic function on (LOGON) switch 25, described in greater detail subsequently, correlated double-sample capacitor 26 connected to the gate of transistor 28, which under the control of sample and hold switch, SH, 29 controls the gate of transistor 30 which loads the sample-hold capacitor, Csh, 32. A correlated double-sample switch, CDS, 34, described in greater detail subsequently, is also connected to the gate of transistor 28. As the amplifier saturates, the photodiode forward biases itself, and the voltage induced across the photodiode is proportional to the log of the flux. Therefore, although the output voltage is not changing, the differential voltage from amplifier output to amplifier input has changed. Various means can be used to output this voltage. In a CTIA, one solution is after the integration time is complete, the output of the amplifier is disconnected allowing the feedback to ‘fly’. Then the detector is shorted, thus adding the log voltage to the output of the feedback capacitor.

The overall response of the circuit is such that out of the total output voltage range of the circuit (2.0 volts, for example), linear mode response is indicated in the 0.0°V to 1.5°V portion of the output swing. Logarithmic response is indicated in the 1.5V to 2.0V portion of the output swing. This significantly increases the dynamic range of the photodiode response. In an example of the CTIA embodiment, a good response might by 3½ orders of magnitude. Adding the log response, gives another 4 orders of magnitude, or more, albeit “compressed”. The output remains monotonic at all times and is automatic and instantaneous.

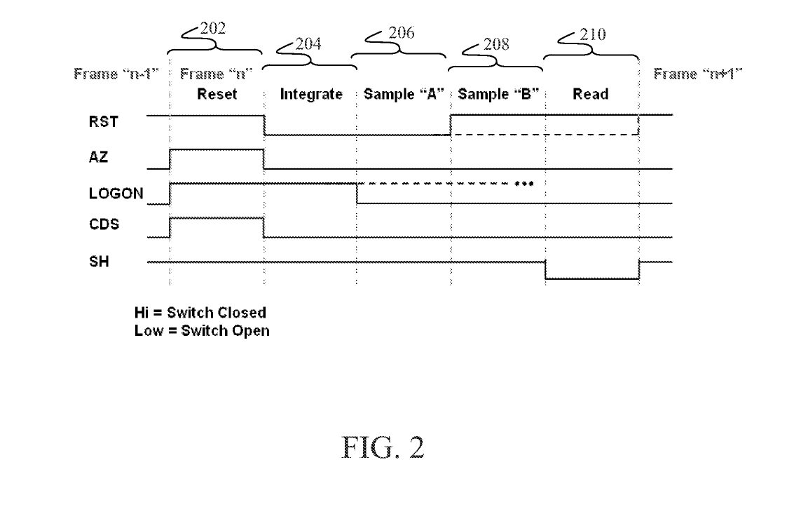

The following sections describe the detailed operation of the circuit in the five segments of its operation during a frame period. Timing relationships required to operate the circuit in automatic lin/log mode or in linear-only mode (dashed lines for RST and LOGON switches apply to linear-only mode) with control of the associated in-cell switches shown in FIG. 2.

In a “RESET” segment 202, the starting configuration of the photodiode is established at the beginning of frame “n”. The respective switch states shown in FIG. 2 are asserted, causing the diode to be shorted and the amplifier to be placed into a reset state.

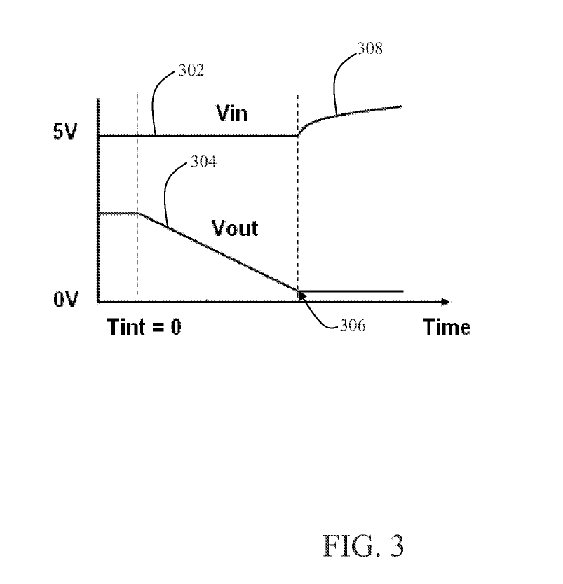

Next, in an INTEGRATE segment 204, with the switch states asserted as shown in FIG. 2, the amplifier integrates photocharge and becomes saturated after a period of time. Saturation time is determined by the relative sizes of the two capacitors Cint and Czero and the intensity of the photon flux exposing the photodiode. Upon Vout saturation, the negative feedback loop of the CTIA amplifier breaks, permitting Vin to execute a logarithmic response because the photodiode becomes forward biased. These conditions are represented in FIG. 3 with Vin shown in trace 302 and Vout in trace 304 with Vout providing a linear response until reaching saturation at point 306. Forward biasing of the diode is shown in the continuation of the Vin trace 308.

There are two sampling techniques. Sample Part A 206 is standard and does not use the LOGON switch 25 while Sample Part B 208 is the log mode and does use the LOGON switch 25.

To implement the standard mode, Sample Part A 206, at the end of integration time, the switches remain as shown in FIG. 2 and the LOGON switch 25 is not used (i.e. remains shorted). The resulting Vout voltage will represent the result of integrating charge in the linear mode; lower voltage refers to more integrated charge.

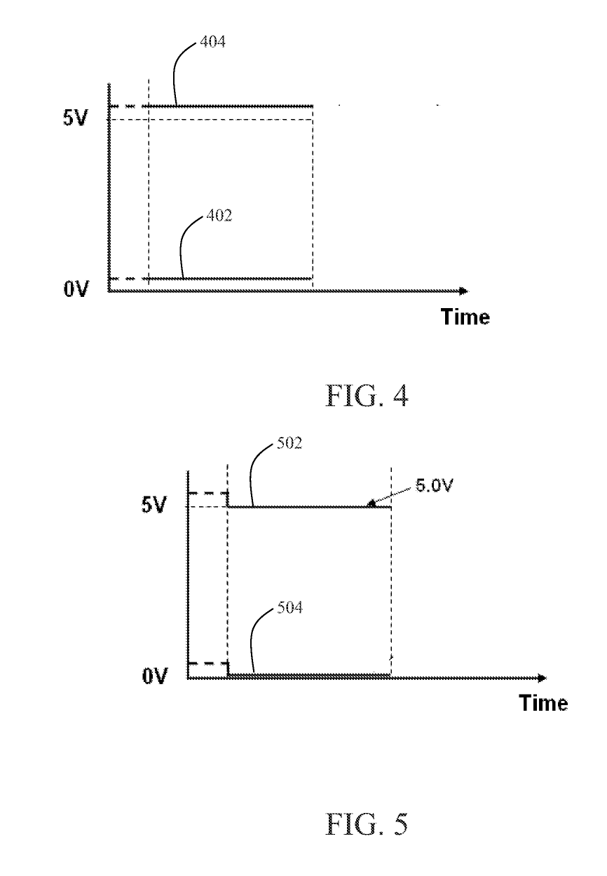

For the Sample Part B 208 or log mode, at the end of the integration time, the Vout voltage will represent the integrated charge. As represented by FIG. 4, if enough light energy is present during the exposure period to drive Vout, trace 402, into saturation, the photodiode becomes forward biased, trace 404, providing a voltage greater than 5.0V.

To implement sampling to measure the signal in Log Mode, the LOGON switch 25 is opened at the end of the integration time as shown in FIG. 2 allowing the integration capacitor to ‘fly’ or retain the integrated voltage plus the log voltage. Next, the detector RST switch 15 is closed, shorting the detector photodiode and offsetting the voltage on the ‘flying’ integration capacitor 26 into the negative voltage direction, trace 502 in FIG. 5. This correlated double-sampling technique has produced a log voltage that has now been subtracted front the output of the integration capacitor, trace 504 in FIG. 5. This resulting lower voltage will be proportional to the logarithm of the photocurrent and the circuit is designed such that the resulting voltage is above the minimum voltage rail of the circuit. This level, in effect, does not saturate and will continue to be driven downward as the photocurrent increases as shown in FIG. 5.

In a READ segment 210, the signal voltage that is held on the output of the integration capacitor 20 (which is automatically transferred to the output of the CDS capacitor 26) is transferred to the sample-hold capacitor, Csh, 32 by closing the sample and hold switch, SH, 28. The signal voltage is thus transferred to the Csh capacitor. Alternatively, the SH could be held closed, during integration and thus the Csh capacitor would be allowed to charge during the entire integration time. With either technique, the SH switch is opened before the photodiode detector of the pixel is reset and the process repeats, thereby saving the signal voltage on the Csh capacitor.

Having now described various embodiments of the invention in detail as required by the patent statutes, those skilled in the art will recognize modifications and substitutions to the specific embodiments disclosed herein. Such modifications are within the scope and intent of the present invention as defined in the following claims.

What is claimed is:

1. A dual mode amplifier for photodiode output comprising:
a photodiode providing a current/voltage input;
an integration capacitor connected to receive the current/voltage input and connected to a voltage output node;
an input capacitor connected to receive the voltage input and driving an operational amplifier having an output connect to the voltage output node;
a sample and hold circuit having a sample and hold capacitor for sampling the integration capacitor;
a log function on (LOGON) switch intermediate the operational amplifier output and the voltage output node;
a reset switch connected to short the photodiode;
said LOGON switch sequentially operable in conjunction with the reset switch at the end of an integration time allowing the integration capacitor to retain an integrated linear voltage plus a log voltage by closing of the reset switch shorting the detector photodiode and offsetting the voltage on the integration capacitor into the negative voltage direction.

2. The dual mode amplifier for photodiode output of claim 1 further comprising a correlated double sample (CDS) capacitor connected to the voltage output node.

3. The dual mode amplifier for photodiode output of claim 1 further comprising an auto-zero switch connected between the operational amplifier input and output and a CDS switch connected to the output of the CDS capacitor.

4. A method for linear and logarithmic measurement of a diode detector comprising:
obtaining a current/voltage input from a diode detector;
integrating the current input on an integration capacitor;
inputting the current/voltage input through a capacitor to an operational amplifier;
charging a double-sample capacitor with an output from the operational amplifier and the integration capacitor;
interrupting the output of the operational amplifier after an integration period and sampling the linear input from the integration capacitor for a first sample period;
shorting the diode detector for sampling the logarithmic input for a second sample period; and
activating a sample and hold circuit to read the double-sample capacitor.

5. The method of claim 4 further comprising resetting the amplifier and CDS capacitor.
